(19) United States
(12) Patent Application Publication
(10) Pub. No.: US 2024/0154007 A1
(43) Pub. Date: May 9, 2024

(54) SEMICONDUCTOR DEVICE

(71) Applicant: ROHM CO., LTD., Kyoto (JP)

(72) Inventor: Tomoaki SHINODA, Kyoto (JP)

(73) Assignee: ROHM CO., LTD., Kyoto (JP)

(21) Appl. No.: 18/502,155

(22) Filed: Nov. 6, 2023

(30) Foreign Application Priority Data
Nov. 7, 2022 (JP) 2022-178165

(51) Int. Cl. H01L 29/40; H01L 29/78

(52) U.S. Cl. CPC H01L 29/404; H01L 29/407; H01L 29/7813

(57) ABSTRACT

A semiconductor device includes: a semiconductor layer; trenches that are formed in the semiconductor layer, extend in first direction, and are spaced apart from each other in second direction, the trenches including a first trench located at outermost side in the second direction, and a second trench adjacent to the first trench; an insulating layer formed on the semiconductor layer and within the trenches; a source electrode formed on the insulating layer; a first buried electrode buried in the first trench; a second buried electrode buried above the first buried electrode in the first trench via the insulating layer; and a contact electrode arranged between two adjacent trenches of the plurality of trenches and connecting the source electrode and the semiconductor layer, wherein the second buried electrode has an upper end in contact with the source electrode and a lower end located below a lower end of the contact electrode.

### CROSS-REFERENCE TO RELATED APPLICATION

This application is based upon and claims the benefit of priority from Japanese Patent Application No. 2022-178165, filed on Nov. 7, 2022, the entire contents of which are incorporated herein by reference.

### TECHNICAL FIELD

The present disclosure relates to a semiconductor device.

### BACKGROUND

A trench gate type transistor using a semiconductor device is a metal-insulator-semiconductor field effect transistor (MISFET) having a split gate structure. In the related art, a MISFET having such a split gate structure is disclosed.

### BRIEF DESCRIPTION OF DRAWINGS

The accompanying drawings, which are incorporated in and constitute a part of the specification, illustrate embodiments of the present disclosure.

FIG. 1 is a schematic plan view of an exemplary semiconductor device according to an embodiment of the present disclosure.

FIG. 2 is a schematic cross-sectional view of the semiconductor device taken along line F2-F2 in FIG. 1.

FIG. 3 is a schematic cross-sectional view of the semiconductor device taken along line F3-F3 in FIG. 1.

FIG. 4 is a schematic cross-sectional view of the semiconductor device taken along line F4-F4 in FIG. 1.

FIG. 5 is a schematic cross-sectional view of the semiconductor device taken along line F5-F5 in FIG. 1.

FIG. 6 is a schematic enlarged plan view of the semiconductor device in a region surrounded by line F6 in FIG. 1.

FIG. 7 is a diagram showing a relationship between a trench width (trench dimension) of a first region of an outer end trench and a drain-source breakdown voltage (BVDSS).

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a semiconductor device of the present disclosure will be described with reference to the accompanying drawings. It should be noted that, for simplicity and clarity of explanation, components shown in the drawings are not necessarily drawn to scale. To facilitate understanding, characteristic portions may be enlarged, and a dimensional ratio of each component is not necessarily the same in each figure. Further, for clarity of illustration, hatching may be omitted in cross-sectional views. The accompanying drawings merely illustrate embodiments of the present disclosure and should not be considered as limiting the present disclosure.

The following detailed description includes devices, systems, and methods embodying exemplary embodiments of the present disclosure. This detailed description is for illustrative purposes only and is not intended to limit the embodiments of the present disclosure or the applications and uses of such embodiments.

[1. Overall Structure of MISFET with Split Gate Structure]

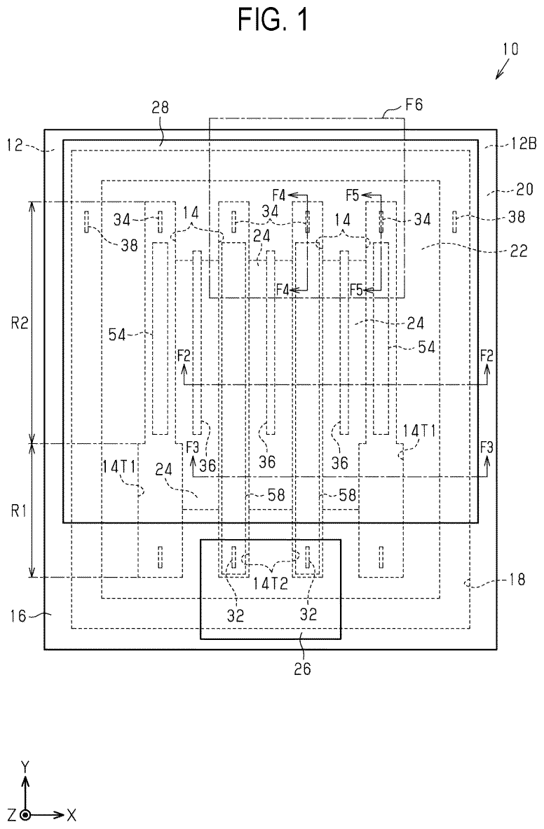

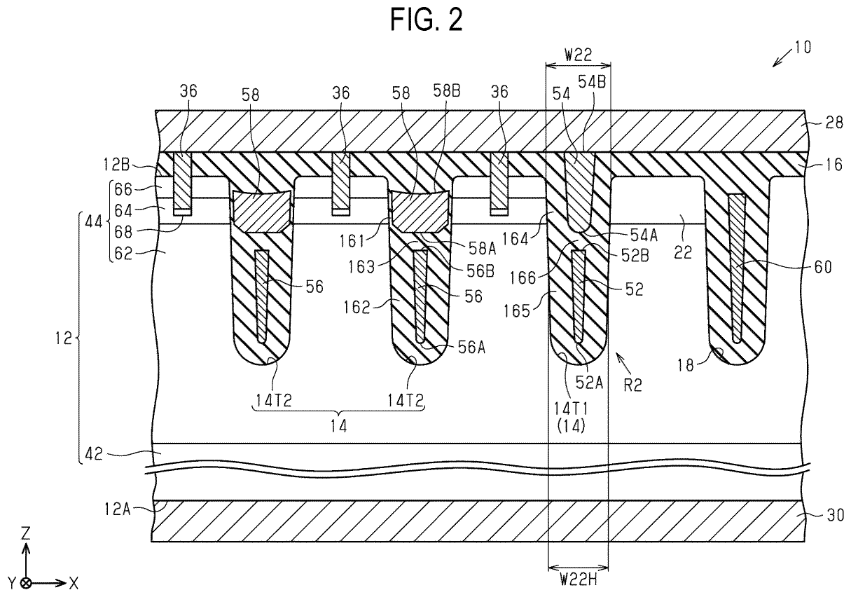

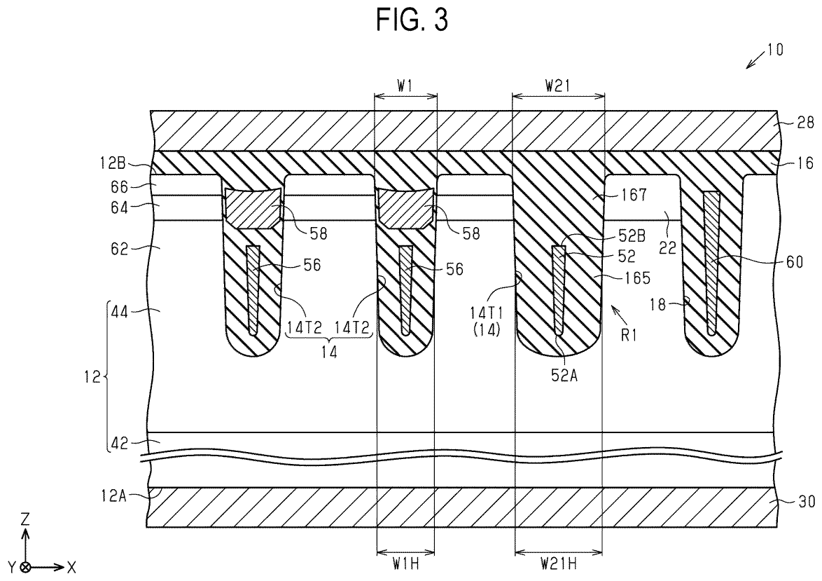

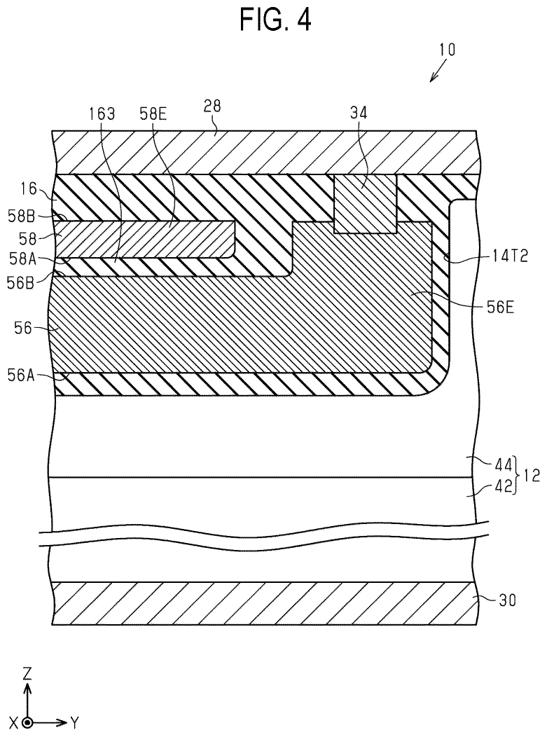

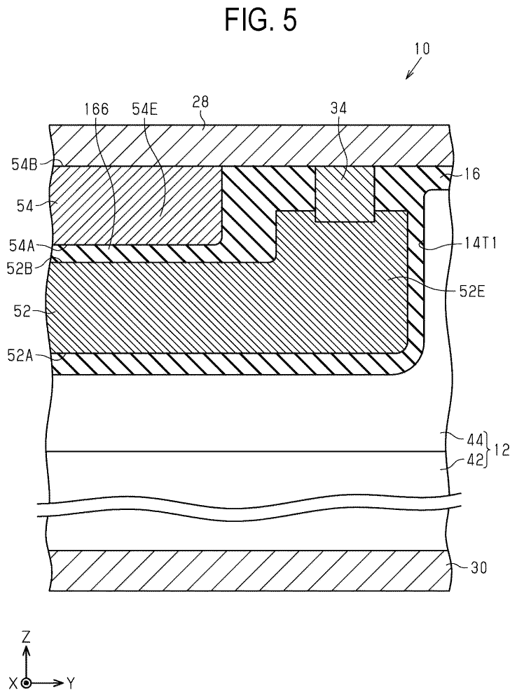

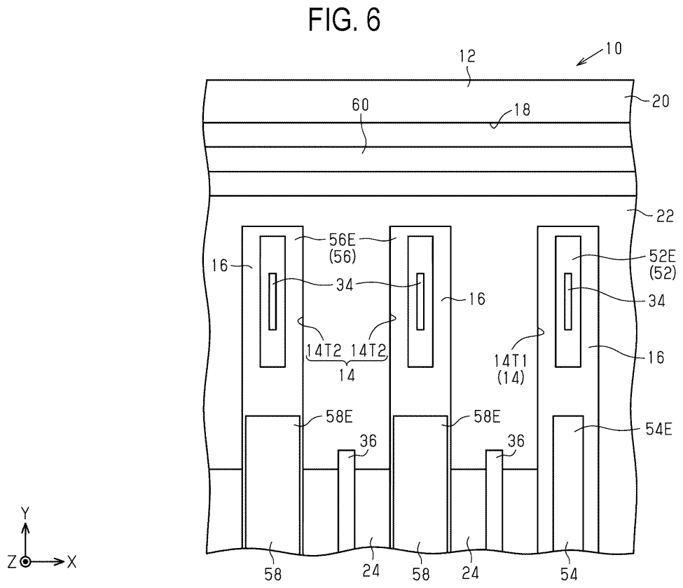

FIG. 1 is a schematic plan view of an exemplary semiconductor device 10 according to an embodiment of the present disclosure. FIGS. 2 to 5 are various cross-sectional views of the semiconductor device 10 shown in FIG. 1, with FIG. 2 being a cross-section taken along line F2-F2 in FIG. 1, FIG. 3 being a cross-section taken along line F3-F3 in FIG. 1, FIG. 4 being a cross-section taken along line F4-F4 in FIG. 1, and FIG. 5 being a cross-section taken along line F5-F5 in FIG. 1, respectively. FIG. 6 is a schematic plan view of the semiconductor device 10 in a region surrounded by line F6 in FIG. 1.

Note that “plan view” as used in the present disclosure refers to viewing an object (the semiconductor device 10 or its constituent elements) in a Z-axis direction of mutually orthogonal X, Y, and Z axes shown in the drawings (for example, FIG. 1), unless explicitly stated otherwise.

As shown in FIG. 1, the semiconductor device 10 is configured as a trench gate type MISFET having a split gate structure. The semiconductor device 10 includes a semiconductor layer 12, a plurality of trenches 14 (four trenches in the example of FIG. 1) formed in the semiconductor layer 12, and an insulating layer 16 formed on the semiconductor layer 12 and in each trench 14. Note that in the example of FIG. 1, only four trenches 14 are shown to avoid complication of illustration, but in reality, a larger number of trenches 14 may be formed.

The semiconductor layer 12 is formed of, for example, silicon (Si). As shown in FIGS. 2 and 3, the semiconductor layer 12 includes a first surface 12A and a second surface 12B opposite the first surface 12A and has a thickness in a direction (Z-axis direction) perpendicular to the first surface 12A. The second surface 12B of the semiconductor layer 12 is adjacent to the insulating layer 16.

As shown in FIG. 1, the plurality of trenches 14 extend in the Y-axis direction in a plan view and are spaced apart from each other in the X-axis direction in a plan view. Note that the Y-axis direction corresponds to a first direction and the X-axis direction corresponds to a second direction orthogonal to the first direction.

The plurality of trenches 14 include a pair of outer end trenches 14T1 located at the outermost side in the X-axis direction (the second direction), and a plurality of gate trenches 14T2 (two gate trenches 14T2 in the example of FIG. 1) arranged between the paired outer end trenches 14T1. The paired outer end trenches 14T1 are trenches 14 of the plurality of trenches 14 located at both ends in the X-axis direction. In one example, the outer end trenches 14T1 each correspond to a first trench. Further, each of the gate trenches 14T2 adjacent to the outer end trenches 14T1 corresponds to a second trench.

Although only two gate trenches 14T2 are shown in the example of FIG. 1, a larger number of gate trenches 14T2 may be formed between the paired outer end trenches 14T1. Alternatively, the number of gate trenches 14T2 may be one. The plurality of gate trenches 14T2 (two gate trenches 14T2 in the example of FIG. 1) may be arranged in, for example, a stripe shape at regular intervals in the X-axis direction. As shown in FIGS. 2 and 3, each trench 14 has an opening in the second surface 12B of the semiconductor layer 12. Further, each trench 14 has a depth in the Z-axis direction and a width in the X-axis direction.

As shown in FIG. 2, each outer end trench 14T1 includes a lower field plate electrode 52 and an upper field plate electrode 54, which are buried within the outer end trench 14T1 (the insulating layer 16 formed in the outer end trench 14T1 in the example of FIG. 2). The upper field plate electrode 54 is located above the lower field plate electrode 52 in the trench depth direction and is separated from the lower field plate electrode 52 by the insulating layer 16.

Each gate trench 14T2 includes a lower field plate electrode 56 and a buried gate electrode 58, which are buried within the gate trench 14T2 (the insulating layer 16 formed in the gate trench 14T2 in the example of FIG. 2). The buried gate electrode 58 is located above the lower field plate electrode 56 in the trench depth direction and is separated from the lower field plate electrode 56 by the insulating layer 16.

In one example, the lower field plate electrode 52 buried in the outer end trench 14T1 corresponds to a first buried electrode, and the upper field plate electrode 54 buried in the outer end trench 14T1 corresponds to a second buried electrode. Further, the lower field plate electrode 56 buried in the gate trench 14T2 corresponds to a third buried electrode, and the buried gate electrode 58 buried in the gate trench 14T2 corresponds to a fourth buried electrode. Details of the lower field plate electrodes 52 and 56, the upper field plate electrode 54, and the buried gate electrode 58 will be described later.

As shown in FIG. 1, the semiconductor device 10 may further include a peripheral trench 18 formed in the semiconductor layer 12. The peripheral trench 18 may be arranged so as to be spaced apart from each trench 14 and to surround all of the trenches 14 in a plan view. As shown in FIGS. 2, 3, and 6, the peripheral trench 18 may include a peripheral electrode 60, which is buried within the peripheral trench 18 (the insulating layer 16 formed in the peripheral trench 18). The peripheral trench 18 may be formed, for example, in the shape of a rectangular frame. Further, the peripheral electrode 60 may be formed in the shape of a rectangular frame along the shape of the peripheral trench 18. The peripheral electrode 60 may be formed of, for example, conductive polysilicon. The peripheral trench 18 corresponds to a third trench, and the peripheral electrode 60 corresponds to a fifth buried electrode.

The second surface 12B of the semiconductor layer 12 may include an n⁻-type region 20 containing n-type impurities, a p⁻-type region 22 containing p-type impurities, and an n⁺-type region 24 containing n-type impurities. In the example of FIG. 1, the n⁻-type region 20 surrounds the peripheral trench 18, and the peripheral trench 18 surrounds the p⁻-type region 22. The n⁺-type region 24 is formed in an element region (active region) between the trenches 14.

The plurality of trenches 14 may be arranged adjacent to both the p⁻-type region 22 and the n⁺-type region 24. In the example of FIG. 1, both end portions of each trench 14 in the Y-axis direction may be adjacent to the p⁻-type region 22. A middle portion of each trench 14 in the Y-axis direction may be adjacent to the n⁺-type region 24.

The semiconductor device 10 further includes a gate electrode 26 and a source electrode 28, which are formed on the insulating layer 16, and a drain electrode 30 (see FIGS. 2 to 5) formed on the first surface 12A of the semiconductor layer 12. The gate electrode 26, the source electrode 28, and the drain electrode 30 may be formed of at least one selected from the group of titanium (Ti), nickel (Ni), gold (Au), silver (Ag), copper (Cu), aluminum (Al), a Cu alloy, and an Al alloy.

As shown in FIG. 1, the gate electrode 26 and the source electrode 28 may be arranged so as to overlap a portion of each trench 14 and a portion of the peripheral trench 18, respectively, in a plan view. Further, each of the gate electrode 26 and the source electrode 28 may at least partially overlap the p⁻-type region 22 in a plan view. The source electrode 28 may overlap at least the entire n⁺-type region 24 in a plan view.

The semiconductor device 10 further includes a plurality of gate contacts 32 (two gate contacts 32 in the example of FIG. 1). Each gate contact 32 is arranged in a region where the gate electrode 26 and the buried gate electrode 58 in each gate trench 14T2 overlap in a plan view, and connects the buried gate electrode 58 to the gate electrode 26. Although a cross-sectional view is omitted, the gate contact 32 penetrates the insulating layer 16 located between the gate electrode 26 and the buried gate electrode 58 in the Z-axis direction.

The semiconductor device 10 further includes a plurality of source contacts 34 (four source contacts 34 in the example of FIG. 1). Each source contact 34 is arranged in a region where the source electrode 28 and the corresponding lower field plate electrodes 52 and 56 in each trench 14 overlap in a plan view (FIGS. 4 and 5). The source contact 34 penetrates the insulating layer 16 located between the source electrode 28 and the lower field plate electrodes 52 and 56 in the Z-axis direction.

For example, in the outer end trench 14T1 (see FIG. 5), the source contact 34 is arranged in a region where the source electrode 28 and the lower field plate electrode 52 overlap in a plan view, and connects the lower field plate electrode 52 to the source electrode 28. Further, in the gate trench 14T2 (see FIG. 4), the source contact 34 is arranged in a region where the source electrode 28 and the lower field plate electrode 56 overlap in a plan view, and connects the lower field plate electrode 56 to the source electrode 28.

As shown in FIG. 1, the semiconductor device 10 further includes one or more line contacts 36 (three line contacts 36 in the example of FIG. 1) arranged between two adjacent trenches 14 among the plurality of trenches 14. The line contact 36 is provided to apply a source potential to the semiconductor layer 12 and connects a contact region 68 (see FIG. 2), which will be described later, formed in the semiconductor layer 12, to the source electrode 28. The line contact 36 extends in the Y-axis direction in a plan view. The line contact 36 corresponds to a contact electrode.

The semiconductor device 10 may further include one or more contacts 38 that connect the peripheral electrode 60 (see FIGS. 2, 3, and 6), which is arranged within the peripheral trench 18, to the source electrode 28. The gate contact 32, the source contact 34, the line contact 36, and the contact 38 may be formed of any metal material. In one example, the contacts 32, 34, 36, and 38 may be formed of at least one selected from the group of tungsten (W), Ti, and titanium nitride (TiN).

As shown in FIGS. 2 and 3, the semiconductor layer 12 may include a semiconductor substrate 42 and an epitaxial layer 44 formed on the semiconductor substrate 42. The semiconductor substrate 42 includes the first surface 12A of the semiconductor layer 12, and the epitaxial layer 44 includes the second surface 12B of the semiconductor layer 12. The semiconductor substrate 42 may be a Si substrate. The epitaxial layer 44 may be a Si layer epitaxially grown on a Si substrate (the semiconductor substrate 42).

The semiconductor substrate 42 corresponds to a drain region of MISFET. The epitaxial layer 44 may include a drift region 62, a body region 64 formed on the drift region 62, and a source region 66 formed on the body region 64. The source region 66 includes the second surface 12B of the semiconductor layer 12. The body region 64 may include the contact region 68 located below the line contact 36.

The drain region formed by the semiconductor substrate 42 may be an n⁺-type region containing n-type impurities. The n-type impurity concentration of the semiconductor substrate 42 may be, for example, 1×10¹⁸ cm⁻³ or more and 1×10²⁰ cm⁻³ or less. The semiconductor substrate 42 may have a thickness of, for example, 50 μm or more and 450 μm or less.

The drift region 62 may be an n⁻-type region containing n-type impurities at a lower concentration than the drain region (the semiconductor substrate 42). The n-type impurity concentration of the drift region 62 may be, for example, 1×10¹⁵ cm⁻³ or more and 1×10¹⁸ cm⁻³ or less. The drift region 62 may have a thickness of, for example, 1 μm or more and 25 μm or less.

The body region 64 is a region containing p-type impurities and may be formed by a portion of the p⁻-type region 22 shown in FIG. 1. The p-type impurity concentration of the body region 64 may be, for example, 1×10¹⁶ cm⁻³ or more and 1×10¹⁸ cm⁻³ or less. The body region 64 may have a thickness of, for example, 0.5 μm or more and 1.5 μm or less.

The source region 66 is a region containing n-type impurities at a higher concentration than the drift region 62 and may be formed by the n⁺-type region 24 shown in FIG. 1. The n-type impurity concentration of the source region 66 may be, for example, 1×10¹⁹ cm⁻³ or more and 1×10²¹ cm⁻³ or less. The source region 66 may have a thickness of, for example, 0.1 μm or more and 1 μm or less.

The contact region 68 may be a p⁺-type region containing p-type impurities. The p-type impurity concentration of the contact region 68 is higher than that of the body region 64 and may be, for example, 1×10¹⁹ cm⁻³ or more and 1×10²¹ cm⁻³ or less.

The n-type impurities may be, for example, phosphorus (P), arsenic (As), and the like. Further, the p-type impurities may be, for example, boron (B), aluminum (Al), and the like.

### [2. Structure of Gate Trench]

Next, a structure of the gate trench 14T2 will be described. Note that since the plurality of gate trenches 14T2 (two gate trenches 14T2 in the example of FIG. 1) have the same structure, a structure of one gate trench 14T2 will be described.

As shown in FIGS. 2 and 3, the gate trench 14T2 has an opening in the second surface 12B of the semiconductor layer 12. The gate trench 14T2 penetrates the source region 66 and the body region 64 of the semiconductor layer 12 and reaches the drift region 62. A depth of the gate trench 14T2 may be, for example, 1 μm or more and 10 μm or less. The depth of the gate trench 14T2 corresponds to a distance in the Z-axis direction from the second surface 12B of the semiconductor layer 12 to a bottom wall of the gate trench 14T2 (the deepest portion of the gate trench 14T2 in a case where the bottom wall is curved).

A sidewall of the gate trench 14T2 may or may not extend in a direction (the Z-axis direction) perpendicular to the second surface 12B of the semiconductor layer 12. In the examples of FIGS. 2 and 3, the sidewall of the gate trench 14T2 is inclined with respect to the Z-axis direction so that a width of the gate trench 14T2 becomes smaller toward the bottom wall. The bottom wall of gate trench 14T2 does not necessarily have to be flat. In the examples of FIGS. 2 and 3, the bottom wall of the gate trench 14T2 is partially or entirely curved.

When the sidewall of the gate trench 14T2 is inclined so that the width of the gate trench 14T2 becomes smaller toward the bottom wall, a width at a specific depth position of the gate trench 14T2 may be defined as the width of the gate trench 14T2. For example, the width of the gate trench 14T2 may be a width W1 of an upper end opening of the gate trench 14T2, which corresponds to the maximum trench width of the gate trench 14T2. Alternatively, the width of the gate trench 14T2 may be a width W1H at the center position of the gate trench 14T2 in the depth direction. The width W1H may correspond to ½ of the maximum trench width of the gate trench 14T2. Alternatively, the width of the gate trench 14T2 may be a width at any other depth position.

In the gate trench 14T2, the lower field plate electrode 56 includes a bottom surface 56A and a top surface 56B. The lower field plate electrode 56 may be formed with a uniform width in the trench depth direction (the Z-axis direction), or may be formed with different widths in the trench depth direction. In the examples of FIGS. 2 and 3, the width of the lower field plate electrode 56 decreases from the top surface 56B toward the bottom surface 56A. The bottom surface 56A and the top surface 56B of the lower field plate electrode 56 may be flat or curved. The bottom surface 56A includes the lower end of the lower field plate electrode 56 (for example, the lowermost portion of the bottom surface 56A), and the top surface 56B includes the upper end of the lower field plate electrode 56 (for example, the uppermost portion of the top surface 56B).

The lower field plate electrode 56 is surrounded by the insulating layer 16 and is spaced apart from the buried gate electrode 58 across the insulating layer 16 in the trench depth direction. The lower field plate electrode 56 may be at the same potential as the source electrode 28. By applying a source voltage to the lower field plate electrode 56, electric field concentration within the gate trench 14T2 may be alleviated, thereby improving a breakdown voltage of the semiconductor device 10. In addition, the lower field plate electrode 56 provides an effect of extending a depletion layer within the semiconductor layer 12, thereby improving a drain-source breakdown voltage.

The buried gate electrode 58 includes a bottom surface 58A and a top surface 58B. The buried gate electrode 58 may be formed with a uniform width in the trench depth direction, or may be formed with different widths in the trench depth direction. In the examples of FIGS. 2 and 3, the buried gate electrode 58 is formed with a substantially uniform width. The buried gate electrode 58 may have a greater width than the lower field plate electrode 56 in the X-axis direction.

The bottom surface 58A and the top surface 58B of the buried gate electrode 58 may be flat or curved. The bottom surface 58A includes the lower end of the buried gate electrode 58 (for example, the lowermost portion of the bottom surface 58A), and the top surface 58B includes the upper end of the buried gate electrode 58 (for example, the uppermost portion of the top surface 58B). The bottom surface 58A of the buried gate electrode 58 at least partially faces the top surface 56B of the lower field plate electrode 56. The top surface 58B of the buried gate electrode 58 may be located below the second surface 12B of the semiconductor layer 12.

The bottom surface 58A (the lower end) of the buried gate electrode 58 may be located below the lower end of the line contact 36 in the trench depth direction. For example, the bottom surface 58A (the lower end) of the buried gate electrode 58 is located below a pn junction interface between the drift region 62 and the body region 64 in the trench depth direction. However, the bottom surface 58A of the buried gate electrode 58 may be located at the same position as or above the pn junction interface between the drift region 62 and the body region 64.

The lower field plate electrode 56 and the buried gate electrode 58 may be formed of, for example, conductive polysilicon. The insulating layer 16 may be formed of, for example, a silicon oxide film (SiO₂). Additionally or alternatively, the insulating layer 16 may include a film formed of an insulating material other than SiO₂, such as silicon nitride (SiN).

Within the gate trench 14T2, the insulating layer 16 includes a gate insulating portion 161 interposed between the buried gate electrode 58 and the semiconductor layer 12 and covering the sidewall of the gate trench 14T2. Therefore, the buried gate electrode 58 and the semiconductor layer 12 are separated from each other across the gate insulating portion 161. When a given voltage is applied to the buried gate electrode 58, a channel is formed in the p-type body region 64 adjacent to the gate insulating portion 161. The semiconductor device 10 is configured to control a flow of electrons in the Z-axis direction between the n⁺-type source region 66 and the n⁻-type drift region 62 via this channel.

Further, the insulating layer 16 includes a lower insulating portion 162 covering the sidewall and the bottom wall of the gate trench 14T2 between the lower field plate electrode 56 and the semiconductor layer 12. The lower insulating portion 162 may be formed on the sidewall of the gate trench 14T2 to be thicker than the gate insulating portion 161. The insulating layer 16 further includes an intermediate insulating portion 163 located between the top surface 56B of the lower field plate electrode 56 and the bottom surface 58A of the buried gate electrode 58.

As shown in FIGS. 4 and 6, the lower field plate electrode 56 includes an end portion 56E and the buried gate electrode 58 includes an end portion 58E at a position corresponding to one end of the gate trench 14T2 in the Y-axis direction. The end portion 56E of the lower field plate electrode 56 is spaced apart from the end portion 58E of the buried gate electrode 58 across the insulating layer 16 and is electrically connected to the source electrode 28 via the source contact 34. The upper surface of the end portion 56E of the lower field plate electrode 56 may be located at the same position as the upper surface of the end portion 58E of the buried gate electrode 58, for example.

Although not shown in the drawings, as described above, the other end portion of the buried gate electrode 58 is electrically connected to the gate electrode 26 via the gate contact 32 at a position corresponding to the other end of the gate trench 14T2 in the Y-axis direction.

### [3. Structure of Outer End Trench]

Next, a structure of the outer end trench 14T1 will be described. Note that since the plurality of outer end trenches 14T1 (two outer end trenches 14T1 in the example of FIG. 1) have the same structure, the structure of one outer end trench 14T1 will be described.

As shown in FIG. 1, the outer end trench 14T1 includes a first region R1 and a second region R2 that are continuous in the Y-axis direction. The first region R1 has a larger width in the X-axis direction than the second region R2 and also has a larger width in the X-axis direction than the gate trench 14T2. That is, the outer end trench 14T1 has a first trench width in the first region R1 and has a second trench width smaller than the first trench width in the second region R2.

The first region R1 may be longer or shorter than the second region R2 in the Y-axis direction. In the example of FIG. 1, the first region R1 is formed to be shorter than the second region R2 in the Y-axis direction. Alternatively, the first region R1 may be formed to have the same length as the second region R2 in the Y-axis direction.

The line contact 36 is adjacent to the second region R2 of the outer end trench 14T1. For example, the length of the first region R1 in the Y-axis direction (in other words, the length of the second region R2) may be determined according to the length of the line contact 36 in the Y-axis direction. For example, the length of the first region R1 may be determined such that the first region R1 is not adjacent to the line contact 36. Since the first region R1 has a larger trench width than the second region R2, in a case where the first region R1 is adjacent to the line contact 36, a region of the semiconductor layer 12 between the outer end trench 14T1 and the gate trench 14T2 becomes narrower. In this case, a formation region for the line contact 36 becomes narrow, which may make it difficult to form the line contact 36. Therefore, it is desirable that the line contact 36 is not adjacent to the first region R1 but only adjacent to the second region R2.

In the outer end trench 14T1, the upper field plate electrode 54 is buried in at least the second region R2 among the first region R1 and the second region R2. In the example of FIG. 1, the upper field plate electrode 54 is buried only in the second region R2 and is not buried in the first region R1. However, the upper field plate electrode 54 may extend not only to the second region R2 but also to the first region R1. For example, the upper field plate electrode 54 may extend to the first region R1 within a range in which the source electrode 28 exists directly above the upper field plate electrode 54 in a plan view.

As shown in FIGS. 2 and 3, the outer end trench 14T1 has an opening in the second surface 12B of the semiconductor layer 12. The outer end trench 14T1 penetrates the source region 66 and the body region 64 of the semiconductor layer 12 and reaches the drift region 62. The depth of the outer end trench 14T1 may be the same as the depth of the gate trench 14T2. Alternatively, the depth of the outer end trench 14T1 may be larger or smaller than the depth of the gate trench 14T2. The depth of the outer end trench 14T1 may be, for example, 1 μm or more and 10 μm or less. The depth of the outer end trench 14T1 corresponds to a distance in the Z-axis direction from the second surface 12B of the semiconductor layer 12 to the bottom wall of the outer end trench 14T1 (the deepest portion of the outer end trench 14T1 in a case where the bottom wall is curved).

The sidewall of the outer end trench 14T1 may or may not extend in a direction (the Z-axis direction) perpendicular to the second surface 12B of the semiconductor layer 12. In the examples of FIGS. 2 and 3, the sidewall of the outer end trench 14T1 is inclined with respect to the Z-axis direction so that the width of the outer end trench 14T1 becomes smaller toward the bottom wall. The bottom wall of the outer end trench 14T1 does not necessarily have to be flat. In the examples of FIGS. 2 and 3, the bottom wall of the outer end trench 14T1 is partially or entirely curved.

When the sidewall of the outer end trench 14T1 is inclined such that the width of the outer end trench 14T1 decreases toward the bottom wall, a width at a specific depth position of the outer end trench 14T1 may be defined as the width of the outer end trench 14T1. As described above, the outer end trench 14T1 has the first trench width in the first region R1, and the second trench width smaller than the first trench width in the second region R2. The trench width of each of the first region R1 and the second region R2 will be described below.

For example, as shown in FIG. 3, the first trench width of the outer end trench 14T1, that is, the width of the outer end trench 14T1 in the first region R1, may be a width W21 of the upper end opening of the outer end trench 14T1 corresponding to the maximum trench width in the first region R1. Alternatively, the first trench width may be the width W21H at the center position of the outer end trench 14T1 in the depth direction in the first region R1. The width W21H may correspond to ½ of the maximum trench width in the first region R1. Alternatively, the first trench width may be a width at any other depth position.

Further, as shown in FIG. 2, the second trench width of the outer end trench 14T1, that is, the width of the outer end trench 14T1 in the second region R2, may be a width W22 of an upper end opening of the outer end trench 14T1 corresponding to the maximum trench width in the second region R2. Alternatively, the second trench width may be a width W22H at the center position of the outer end trench 14T1 in the depth direction in the second region R2. The width W22H may correspond to ½ of the maximum trench width in the second region R2. Alternatively, the second trench width may be a width at any other depth position.

Note that the width W22 of the outer end trench 14T1 may be the same as the width W1 of the gate trench 14T2 and the width W22H of the outer end trench 14T1 may be the same as the width W1H of the gate trench 14T2.

In the outer end trench 14T1, the lower field plate electrode 52 includes a bottom surface 52A and a top surface 52B. The lower field plate electrode 52 may be formed with a uniform width in the trench depth direction (the Z-axis direction), or may be formed with different widths in the trench depth direction. In the examples of FIGS. 2 and 3, the width of the lower field plate electrode 52 decreases from the top surface 52B toward the bottom surface 52A. The bottom surface 52A and the top surface 52B of the lower field plate electrode 52 may be flat or curved. The bottom surface 52A includes the lower end of the lower field plate electrode 52 (for example, the lowermost portion of the bottom surface 52A), and the top surface 52B includes the upper end of the lower field plate electrode 52 (for example, the uppermost portion of the top surface 52B).

The lower field plate electrode 52 is surrounded by the insulating layer 16 and is spaced apart from the upper field plate electrode 54 across the insulating layer 16 in the trench depth direction. The lower field plate electrode 52 may be at the same potential as the source electrode 28. By applying a source voltage to the lower field plate electrode 52, the lower field plate electrode 52 provides an effect of extending a depletion layer within the semiconductor layer 12, thereby improving the drain-source breakdown voltage of the semiconductor device 10. Note that the lower field plate electrode 52 in the outer end trench 14T1 may have the same configuration as the lower field plate electrode 56 in the gate trench 14T2, for example.

The upper field plate electrode 54 includes a bottom surface 54A and a top surface 54B. The upper field plate electrode 54 may be formed with a uniform width in the trench depth direction, or may be formed with different widths in the trench depth direction. In the example of FIG. 2, the width of the upper field plate electrode 54 decreases from the top surface 54B toward the bottom surface 54A. The upper field plate electrode 54 may have a greater width than the lower field plate electrode 52 in the X-axis direction.

The bottom surface 54A of the upper field plate electrode 54 may be flat or curved. The bottom surface 54A includes the lower end of the upper field plate electrode 54 (for example, the lowermost portion of the bottom surface 54A). The bottom surface 54A of the upper field plate electrode 54 at least partially faces the top surface 52B of the lower field plate electrode 52. The top surface 54B of the upper field plate electrode 54 may be flat. The top surface 54B of the upper field plate electrode 54 is provided as the upper end of the upper field plate electrode 54 in contact with the source electrode 28. In the example of FIG. 2, the entire top surface 54B of the upper field plate electrode 54 is in contact with the source electrode 28.

The bottom surface 54A (the lower end) of the upper field plate electrode 54 may be located below the lower end of the line contact 36 in the trench depth direction. For example, the bottom surface 54A (the lower end) of the upper field plate electrode 54 may be located below the pn junction interface between the drift region 62 and the body region 64 in the trench depth direction. In the example of FIG. 2, the bottom surface 54A (the lower end) of the upper field plate electrode 54 is located at the same position as or below the bottom surface 58A (the lower end) of the buried gate electrode 58 in the trench depth direction. However, the bottom surface 54A of the upper field plate electrode 54 may be located at the same position as or above the pn junction interface between the drift region 62 and the body region 64.

The upper field plate electrode 54 is surrounded by the insulating layer 16 except for the top surface 54B. Since the upper field plate electrode 54 is connected to the source electrode 28, it has the same potential as the source electrode 28. By applying a source voltage to the upper field plate electrode 54, the upper field plate electrode 54 provides the effect of extending the depletion layer within the semiconductor layer 12, thereby improving the drain-source breakdown voltage of the semiconductor device 10.

The upper field plate electrode 54 may be formed of a material that is different from a material that the lower field plate electrode 52 is formed of. For example, the lower field plate electrode 52 may be formed of conductive polysilicon. On the other hand, the upper field plate electrode 54 may be formed of at least one selected from the group of tungsten (W), Ti, titanium nitride (TiN), copper (Cu), aluminum (Al), a Cu alloy, and an Al alloy. For example, the upper field plate electrode 54 is formed of the same material as the line contact 36. When the upper field plate electrode 54 and the line contact 36 are formed of the same material, it is advantageous in that both of them may be formed in the same process. Further, the upper field plate electrode 54 may be formed of the same material and in the same process as the gate contact 32 and the source contact 34.

As shown in FIG. 2, in the second region R2 of the outer end trench 14T1, the insulating layer 16 includes an upper insulating portion 164 that is interposed between the upper field plate electrode 54 and the semiconductor layer 12 and covers the sidewall of the outer end trench 14T1. The insulating layer 16 also includes a lower insulating portion 165 that covers the sidewall and the bottom wall of the outer end trench 14T1 between the lower field plate electrode 52 and the semiconductor layer 12. The lower insulating portion 165 may be formed on the sidewall of the outer end trench 14T1 so as to be thicker than the upper insulating portion 164. The insulating layer 16 further includes an intermediate insulating portion 166 located between the top surface 52B of the lower field plate electrode 52 and the bottom surface 54A of the upper field plate electrode 54.

In the outer end trench 14T1, the top surface 52B (the upper end) of the lower field plate electrode 52 and the bottom surface 54A (the lower end) of the upper field plate electrode 54 are separated from each other by a first distance via an intermediate insulating portion 166. On the other hand, in the gate trench 14T2, the top surface 56B (the upper end) of the lower field plate electrode 56 and the bottom surface 58A (the lower end) of the buried gate electrode 58 are separated from each other by a second distance via the intermediate insulating portion 163. In this configuration, the first distance may be equal to or less than the second distance. As the first distance becomes shorter, an electric field concentration relaxation effect obtained by using both the lower field plate electrode 52 and the upper field plate electrode 54 is enhanced, thereby improving the drain-source breakdown voltage.

As shown in FIG. 3, in the first region R1 of the outer end trench 14T1, the insulating layer 16 includes a lower insulating portion 165 and an upper insulating portion 167. The upper insulating portion 167 is formed on the lower insulating portion 165 and covers the top surface 52B of the lower field plate electrode 52 and the sidewall of the outer end trench 14T1.

As shown in FIGS. 5 and 6, the lower field plate electrode 52 includes an end portion 52E and the upper field plate electrode 54 includes an end portion 54E at a position corresponding to one end of the outer end trench 14T1 in the Y-axis direction. The end portion 52E of the lower field plate electrode 52 is spaced apart from the end portion 54E of the upper field plate electrode 54 across the insulating layer 16 and is electrically connected to the source electrode 28 via the source contact 34. Further, as shown in FIG. 5, regarding the upper field plate electrode 54, the entire top surface 54B of the upper field plate electrode 54, including the end portion 54E, is in contact with the source electrode 28.

### [4. Operation of Semiconductor Device]

In the semiconductor device 10, the lower field plate electrode 56 and the buried gate electrode 58 are buried in the gate trench 14T2, and the lower field plate electrode 52 and the upper field plate electrode 54 are buried in the outer end trench 14T1. In this configuration, the lower field plate electrode 56 in the gate trench 14T2 and the lower field plate electrode 52 and the upper field plate electrode 54 in the outer end trench 14T1 have the effect of extending a depletion layer within the semiconductor layer 12, thereby improving the drain-source breakdown voltage.

In the gate trench 14T2, the lower field plate electrode 56 and the buried gate electrode 58 are separated from each other by the insulating layer 16. Similarly, in the outer end trench 14T1, the lower field plate electrode 52 and the upper field plate electrode 54 are separated from each other by the insulating layer 16.

Here, in a case where the lower field plate electrode 52 and the upper field plate electrode 54 in the outer end trench 14T1 are integrated without being separated by the insulating layer 16, it is expected that a higher field plate effect (electric field concentration relaxation effect) will be obtained. On the other hand, in this case, there is a large difference in trench internal structure between the gate trench 14T2 and the outer end trench (including a single field plate electrode), which are adjacent to each other. For example, there is a significant difference between the thickness of the insulating layer 16 within the gate trench 14T2 and the thickness of the insulating layer 16 within the outer edge trench (including a single field plate electrode).

The large difference in trench internal structure between two adjacent trenches may cause a stress between the adjacent trenches, and such a stress may also cause crystal defects in the semiconductor layer 12 between the adjacent trenches. Such crystal defects may result in a decrease in reliability of the semiconductor device 10.

In consideration of this point, the lower field plate electrode 52 and the upper field plate electrode 54 in the outer end trench 14T1 are separated from each other by the insulating layer 16. In this structure, the difference in trench internal structure between the gate trench 14T2 and the outer end trench 14T1, which are adjacent to each other, is reduced, thereby suppressing crystal defects from being generated in the semiconductor layer 12 between the adjacent trenches 14T1 and 14T2. This makes it possible to improve the breakdown voltage of the semiconductor device 10 and suppress crystal defects in the semiconductor device 10.

Further, the outer end trench 14T1 includes the first region R1 and the second region R2 that are continuous in the Y-axis direction. The first region R1 has a width (the first trench width) larger than the second region R2 in the X-axis direction, and a width (the second trench width) larger than the gate trench 14T2 in the X-axis direction. In this structure, a distance between the gate trench 14T2 and the first region R1 of the outer end trench 14T1 (see FIG. 3) is smaller than a distance between the gate trench 14T2 and the second region R2 of the outer end trench 14T1 (see FIG. 2). As a result, a region of the semiconductor layer 12 between the gate trench 14T2 and the outer end trench 14T1 is reduced, such that the occurrence of breakdown at the pn junction interface between the drift region 62 and the body region 64 is suppressed, thereby improving the drain-source breakdown voltage.

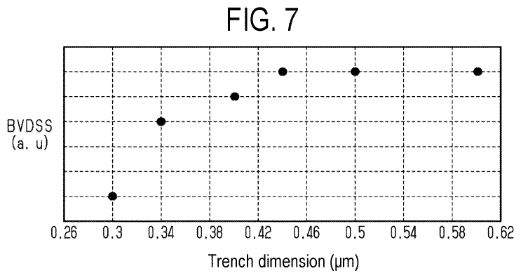

FIG. 7 is a diagram showing a relationship between the first trench width (a trench dimension shown on the horizontal axis in FIG. 7) of the first region R1 of the outer end trench 14T1 and the drain-source breakdown voltage (BVDSS shown on the vertical axis in FIG. 7). As shown in FIG. 7, as the trench dimension (that is, the first trench width of the first region R1) increases, the BVDSS increases. This indicates that the BVDSS increases as the distance between the gate trench 14T2 and the outer end trench 14T1 (the region of the semiconductor layer 12 between them) decreases.

Further, the line contact 36 is adjacent to the second region R2 of the outer end trench 14T1. In a case where the first region R1 of the outer end trench 14T1 is adjacent to the line contact 36, since the region of the semiconductor layer 12 between the outer end trench 14T1 and the gate trench 14T2 becomes narrower, the formation region of the line contact 36 becomes narrower. In this respect, since the line contact 36 is adjacent to the second region R2 of the outer end trench 14T1 and not adjacent to the first region R1, it is not difficult to form the line contact 36.

The semiconductor device 10 according to the embodiment of the present disclosure has the following advantages.
(1) The outer end trench 14T1 includes the lower field plate electrode 52 and the upper field plate electrode 54, which are separated from each other by the insulating layer 16. The gate trench 14T2 includes the lower field plate electrode 56 and the buried gate electrode 58, which are separated from each other by the insulating layer 16. According to this configuration, since the difference in trench internal structure between the gate trench 14T2 and the outer end trench 14T1, which are adjacent to each other, is reduced, the occurrence of crystal defects in the semiconductor layer 12 between the adjacent trenches 14T1 and 14T2 is suppressed. This makes it possible to improve the breakdown voltage of the semiconductor device 10 and suppress crystal defects in the semiconductor device 10.
(2) The line contact 36 connecting the source electrode 28 and the semiconductor layer 12 is provided between adjacent trenches 14 among the plurality of trenches 14. The upper field plate electrode 54 includes the top surface 54B in contact with source electrode 28, and the bottom surface 54A located below the lower end of the line contact 36 in the trench depth direction. According to this configuration, since the top surface 54B of the upper field plate electrode 54 is in contact with the source electrode 28, the potential (source potential) applied to the upper field plate electrode 54 is stabilized. Further, since the bottom surface 54A of the upper field plate electrode 54 is located below the lower end of the line contact 36, the upper field plate electrode 54 extends to the vicinity of the pn junction interface between the drift region 62 and the body region 64 in the trench depth direction. As a result, the field plate effect using the upper field plate electrode 54 may be stably obtained.
(3) In the outer end trench 14T1, the upper field plate electrode 54 is formed of a material that is different from the material that the lower field plate electrode 52 is formed of. According to this configuration, the conductive material for the upper field plate electrode 54 may be selected without depending on the conductive material (for example, conductive polysilicon) for the lower field plate electrode 52. For example, a material in consideration of bonding with the source electrode 28, a material which is easier to be buried, a material which has higher conductivity, etc. may be selected.
(4) The upper field plate electrode 54 in the outer end trench 14T1 is formed of the same material as the line contact 36. According to this configuration, the upper field plate electrode 54 and the line contact 36 may be formed simultaneously in the same process without changing a process flow, which facilitates manufacturing them.
(5) The bottom surface 58A (the lower end) of the buried gate electrode 58 is located below the lower end of the line contact 36 in the trench depth direction. Further, the bottom surface 54A (the lower end) of the upper field plate electrode 54 is located at the same position as or below the bottom surface 58A (the lower end) of the buried gate electrode 58 in the trench depth direction. According to this configuration, the field plate effect obtained by using the upper field plate electrode 54 may be enhanced, thereby further improving the drain-source breakdown voltage of the semiconductor device 10.
(6) In the outer end trench 14T1, the top surface 52B (the upper end) of the lower field plate electrode 52 and the bottom surface 54A (the lower end) of the upper field plate electrode 54 are separated from each other by the first distance via the intermediate insulating portion 166. On the other hand, in the gate trench 14T2, the top surface 56B (the upper end) of the lower field plate electrode 56 and the bottom surface 58A (the lower end) of the buried gate electrode 58 are separated from each other by the second distance via the intermediate insulating portion 163. In this configuration, the first distance may be equal to or less than the second distance. As the first distance becomes shorter, the field plate effect obtained by using both the lower field plate electrode 52 and the upper field plate electrode 54 is enhanced, thereby improving the drain-source breakdown voltage.
(7) In the outer end trench 14T1, the first region R1 has the larger width in the X-axis direction than the second region R2 and also has a larger width in the X-axis direction than the gate trench 14T2. According to this configuration, the distance between the gate trench 14T2 and the first region R1 of the outer end trench 14T1 (see FIG. 3) is smaller than the distance between the gate trench 14T2 and the second region R2 of the outer end trench 14T1 (see FIG. 2). As a result, the region of the semiconductor layer 12 between the gate trench 14T2 and the outer end trench 14T1 is reduced, such that the occurrence of breakdown at the pn junction interface between the drift region 62 and the body region 64 is suppressed, thereby improving the drain-source breakdown voltage. In other words, even in a case where the field plate effect obtained by the first region R1 of the outer end trench 14T1 is smaller than the field plate effect obtained by the second region R2, the same breakdown voltage may be achieved in the first region R1 and the second region R2.
(8) The line contact 36 is adjacent to the second region R2 of the outer end trench 14T1. In a case where the first region R1 of the outer end trench 14T1 is adjacent to the line contact 36, since the region of the semiconductor layer 12 between the outer end trench 14T1 and the gate trench 14T2 becomes narrower, the formation region of the line contact 36 becomes narrower. In this respect, since the line contact 36 is adjacent to the second region R2 of the outer end trench 14T1 and not adjacent to the first region R1, it is not difficult to form the line contact 36.
(9) The upper field plate electrode 54 is buried in at least the second region R2 among the first region R1 and the second region R2 of the outer end trench 14T1. As a result, the field plate effect may be enhanced in the second region R2 having the smaller trench width (the second trench width) than the first region R1, thereby improving the drain-source breakdown voltage. Further, when the upper field plate electrode 54 is also buried in the first region R1, both an improvement in breakdown voltage due to a reduction in the distance between the first region R1 and the adjacent gate trench 14T2 and an improvement in breakdown voltage by the field plate effect may be obtained in the first region R1 having the larger trench width (the first trench width).
(10) The second region R2 is longer than the first region R1 in the Y-axis direction. According to this configuration, the field plate effect obtained by using the upper field plate electrode 54 may be enhanced, thereby improving the breakdown voltage.
(11) The semiconductor device 10 includes the peripheral trench 18 located on the opposite side of the gate trench 14T2 with respect to the outer end trench 14T1 in a plan view and extending in the Y-axis direction, and the peripheral electrode 60 buried in the peripheral trench 18. According to this configuration, a stress generated between the outer end trench 14T1 and the peripheral trench 18 acts to cancel out or reduce a stress generated between the outer end trench 14T1 and the gate trench 14T2. As a result, crystal defects that may be generated between the outer end trench 14T1 and the gate trench 14T2 may be suppressed.

### [Modifications]

Each of the above-described embodiments may be modified and implemented as follows. In addition, the above-described embodiment and the following modifications may be implemented in combination unless technically contradictory.

In the above-described embodiments, the outer end trench 14T1 includes the first region R1 and the second region R2, but may include only the second region R2. That is, the outer end trench 14T1 may have a uniform trench width in the Y-axis direction, similarly to the gate trench 14T2.

In the above-described embodiments, the second region R2 is formed to be longer than the first region R1 in the Y-axis direction (the first direction), but instead of this, the first region R1 may be formed to be longer than the second region R2 in the Y-axis direction.

The peripheral electrode 60 buried in the peripheral trench 18 may not be connected to the source electrode 28. The peripheral electrode 60 may be in an electrically floating state. Also in this case, the peripheral trench 18 (the peripheral electrode 60) functions as a dummy trench (dummy electrode) configured to cancel out or reduce the stress generated between the outer end trench 14T1 and the gate trench 14T2.

The planar layout of the semiconductor device 10 is not limited to that shown in FIG. 1. For example, the peripheral trench 18 and each trench 14 may be connected to each other. Alternatively, the peripheral trench 18 and the peripheral electrode 60 may be omitted. In this case, in the example of FIG. 1, the p-type region 22 may be formed only in a region between a plurality of trenches 14 (between the outer end trench 14T1 and the gate trench 14T2 and between the adjacent gate trenches 14T2).

The term “on” as used in the present disclosure includes meanings of “on” and “above” unless clearly stated otherwise in the context. Therefore, an expression “a first element is mounted on a second element” is intended to mean that in some embodiments, the first element may be directly arranged on the second element in contact with the second element, while in other embodiments, the first element may be arranged above the second element without contacting the second element. That is, the term “on” does not exclude a structure in which other elements are formed between the first element and the second element.

The Z direction used in the present disclosure does not necessarily have to be the vertical direction, and it does not have to be exactly the same as the vertical direction. Therefore, in various structures (for example, the structure shown in FIG. 6) according to the present disclosure, the “upper” and “lower” in the Z-axis direction described herein are not limited to the “upper” and “lower” in the vertical direction. For example, the X-axis direction may be the vertical direction, or the Y-axis direction may be the vertical direction.

Ordinal numbers such as “first” and “second” used in the present disclosure are merely used to clearly distinguish components, and are not always essential to have the components in order.

### [Supplementary Notes]

The technical features that may be understood from the above-described embodiments and modifications are described below. In addition, components described in supplementary notes are labeled in parentheses with the reference numerals of the corresponding components in the embodiments. The reference numerals are provided as examples to aid understanding, and the components described in the supplementary notes should not be limited to the components indicated by the reference numerals.

### (Supplementary Note A1)

A semiconductor device (10) including:
a semiconductor layer (12);
a plurality of trenches (14) that are formed in the semiconductor layer (12), extend in a first direction in a plan view, and are spaced apart from each other in a second direction orthogonal to the first direction in a plan view, the plurality of trenches (14) including a first trench (14T1) located at an outermost side in the second direction, and a second trench (14T2) adjacent to the first trench (14T1);
an insulating layer (16) formed on the semiconductor layer (12) and within the plurality of trenches (14);
a source electrode (28) formed on the insulating layer (16);
a first buried electrode (52) buried in the first trench (14T1);
a second buried electrode (54) buried above the first buried electrode (52) in the first trench (14T1) via the insulating layer (16);
a third buried electrode (56) buried in the second trench (14T2);
a fourth buried electrode (58) buried above the third buried electrode (56) in the second trench (14T2) via the insulating layer (16); and
a contact electrode (36) that is arranged between two adjacent trenches of the plurality of trenches (14) and configured to connect the source electrode (28) and the semiconductor layer (12),
wherein the second buried electrode (54) has an upper end (54B) in contact with the source electrode (28) and a lower end (54A) located below a lower end of the contact electrode (36) in a trench depth direction.

### (Supplementary Note A2)

The semiconductor device (10) of Supplementary Note A1, wherein the second buried electrode (54) is formed of a material different from a material that the first buried electrode (52) is formed of.

### (Supplementary Note A3)

The semiconductor device (10) of Supplementary Note A1 or A2, wherein the second buried electrode (54) is formed of a material which is the same as a material that the contact electrode (36) is formed of.

### (Supplementary Note A4)

The semiconductor device (10) of any one of Supplementary Notes A1 to A3, wherein a lower end (58A) of the fourth buried electrode (58) is located below the lower end of the contact electrode (36) in the trench depth direction, and
wherein the lower end (54A) of the second buried electrode (54) is located at the same position as or below the lower end (58A) of the fourth buried electrode (58) in the trench depth direction.

### (Supplementary Note A5)

The semiconductor device (10) of any one of Supplementary Notes A1 to A4, wherein in the first trench (14T1), an upper end (52B) of the first buried electrode (52) and the lower end (54A) of the second buried electrode (54) are separated from each other by a first distance,
wherein in the second trench (14T2), an upper end (56B) of the third buried electrode (56) and the lower end (58A) of the fourth buried electrode (58) are separated from each other by a second distance, and
wherein the first distance is equal to or less than the second distance.

### (Supplementary Note A6)

The semiconductor device (10) of any one of Supplementary Notes A1 to A5, wherein the first trench (14T1) includes a first region (R1) and a second region (R2) that are continuous in the first direction,
wherein the first region (R1) has a greater width than the second region (R2) in the second direction and a greater width than the second trench (14T2) in the second direction, and
wherein the contact electrode (36) is adjacent to the second region (R2) of the first trench (14T1).

### (Supplementary Note A7)

The semiconductor device (10) of Supplementary Note A6, wherein the second buried electrode (54) is buried in at least the second region (R2) among the first region (R1) and the second region (R2) of the first trench (14T1).

### (Supplementary Note A8)

The semiconductor device (10) of Supplementary Note A6 or A7, wherein the first region (R1) is longer than the second region (R2) in the first direction.

### (Supplementary Note A9)

The semiconductor device (10) of Supplementary Note A6 or A7, wherein the second region (R2) is longer than the first region (R1) in the first direction.

### (Supplementary Note A10)

The semiconductor device (10) of any one of Supplementary Notes A1 to A9, further including:
a third trench (18) that is located opposite the second trench (14T2) with respect to the first trench (14T1) in a plan view and extends in the first direction; and
a fifth buried electrode (60) buried in the third trench (18).

### (Supplementary Note B 1)

A semiconductor device (10) including:
a semiconductor layer (12);
a plurality of trenches (14) that are formed in the semiconductor layer (12), extend in a first direction in a plan view, and are spaced apart from each other in a second direction orthogonal to the first direction in a plan view, the plurality of trenches (14) including a first trench (14T1) located at an outermost side in the second direction, and a second trench (14T2) adjacent to the first trench (14T1);
an insulating layer (16) formed on the semiconductor layer (12) and within the plurality of trenches (14);
a first buried electrode (52) buried in the first trench (14T1);
a second buried electrode (54) buried above the first buried electrode (52) in the first trench (14T1) via the insulating layer (16);
a third buried electrode (56) buried in the second trench (14T2);
a fourth buried electrode (58) buried above the third buried electrode (56) in the second trench (14T2) via the insulating layer (16); and
a contact electrode (36) that is arranged between two adjacent trenches of the plurality of trenches (14) and configured to apply a source potential to the semiconductor layer (12),
wherein the first trench (14T1) includes a first region (R1) and a second region (R2) that are continuous in the first direction,
wherein the first region (R1) has a greater width than the second region (R2) in the second direction and a greater width than the second trench (14T2) in the second direction, and
wherein the contact electrode (36) is adjacent to the second region (R2) of the first trench (14T1).

### (Supplementary Note C1)

The semiconductor device (10) including:
a semiconductor layer (12);
a plurality of trenches (14) that are formed in the semiconductor layer (12), extend in a first direction in plan view, and are spaced apart from each other in a second direction orthogonal to the first direction in the plan view, the plurality of trenches (14) including a first trench (14T1) located at an outermost side in the second direction, and a second trench (14T2) adjacent to the first trench (14T1);
an insulating layer (16) formed on the semiconductor layer (12) and within the plurality of trenches (14);
a first buried electrode (52) buried in the first trench (14T1);
a second buried electrode (54) buried above the first buried electrode (52) in the first trench (14T1) via the insulating layer (16);
a third buried electrode (56) buried in the second trench (14T2);
a fourth buried electrode (58) buried above the third buried electrode (56) in the second trench (14T2) via the insulating layer (16); and
a contact electrode (36) that is arranged between two adjacent trenches of the plurality of trenches (14) and configured to apply a source potential to the semiconductor layer (12),
wherein the second buried electrode (54) is formed of a material different from a material that the first buried electrode (52) is formed of.

The above description is merely an example. Those skilled in the art will appreciate that more combinations and substitutions are possible beyond the components and methods (manufacturing processes) listed to illustrate the techniques of the present disclosure. The present disclosure is intended to cover all alternatives, modifications, and changes that fall within the scope of the present disclosure, including the claims.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor layer;
a plurality of trenches that are formed in the semiconductor layer, extend in a first direction in a plan view, and are spaced apart from each other in a second direction orthogonal to the first direction in a plan view, the plurality of trenches including a first trench located at an outermost side in the second direction, and a second trench adjacent to the first trench;
an insulating layer formed on the semiconductor layer and within the plurality of trenches;
a source electrode formed on the insulating layer;
a first buried electrode buried in the first trench;
a second buried electrode buried above the first buried electrode in the first trench via the insulating layer;
a third buried electrode buried in the second trench;
a fourth buried electrode buried above the third buried electrode in the second trench via the insulating layer; and
a contact electrode that is arranged between two adjacent trenches of the plurality of trenches and configured to connect the source electrode and the semiconductor layer,
wherein the second buried electrode has an upper end in contact with the source electrode and a lower end located below a lower end of the contact electrode in a trench depth direction.

2. The semiconductor device of claim 1, wherein the second buried electrode is formed of a material different from a material that the first buried electrode is formed of.

3. The semiconductor device of claim 1, wherein the second buried electrode is formed of a material which is the same as a material that the contact electrode is formed of.

4. The semiconductor device of claim 1, wherein a lower end of the fourth buried electrode is located below the lower end of the contact electrode in the trench depth direction, and
wherein the lower end of the second buried electrode is located at the same position as or below the lower end of the fourth buried electrode in the trench depth direction.

5. The semiconductor device of claim 1, wherein in the first trench, an upper end of the first buried electrode and the lower end of the second buried electrode are separated from each other by a first distance,
wherein in the second trench, an upper end of the third buried electrode and a lower end of the fourth buried electrode are separated from each other by a second distance, and
wherein the first distance is equal to or less than the second distance.

6. The semiconductor device of claim 1, wherein the first trench includes a first region and a second region that are continuous in the first direction,
wherein the first region has a greater width than the second region in the second direction and a greater width than the second trench in the second direction, and
wherein the contact electrode is adjacent to the second region of the first trench.

7. The semiconductor device of claim 6, wherein the second buried electrode is buried in at least the second region among the first region and the second region of the first trench.

8. The semiconductor device of claim 6, wherein the first region is longer than the second region in the first direction.

9. The semiconductor device of claim 6, wherein the second region is longer than the first region in the first direction.

10. The semiconductor device of claim 1, further comprising:
a third trench that is located opposite the second trench with respect to the first trench in a plan view and extends in the first direction; and
a fifth buried electrode buried in the third trench.

11. A semiconductor device comprising:
a semiconductor layer;
a plurality of trenches that are formed in the semiconductor layer, extend in a first direction in a plan view, and are spaced apart from each other in a second direction orthogonal to the first direction in a plan view, the plurality of trenches including a first trench located at an outermost side in the second direction, and a second trench adjacent to the first trench;
an insulating layer formed on the semiconductor layer and within the plurality of trenches;
a first buried electrode buried in the first trench;
a second buried electrode buried above the first buried electrode in the first trench via the insulating layer;
a third buried electrode buried in the second trench;
a fourth buried electrode buried above the third buried electrode in the second trench via the insulating layer; and
a contact electrode that is arranged between two adjacent trenches of the plurality of trenches and configured to apply a source potential to the semiconductor layer,
wherein the first trench includes a first region and a second region that are continuous in the first direction,
wherein the first region has a greater width than the second region in the second direction and a greater width than the second trench in the second direction, and
wherein the contact electrode is adjacent to the second region of the first trench.
